(19) United States
(12) Patent Application Publication
(10) Pub. No.: US 2026/0293209 A1
(43) Pub. Date: Sep. 24, 2026

(54) SEMICONDUCTOR STRUCTURE

(71) Applicant: Taiwan Semiconductor Manufacturing Company, Ltd., Hsinchu (TW)

(72) Inventors: Ken-Ichi GOTO, Hsinchu County (TW); Gerben DOORNBOS, Kessel-Lo (BE); Georgios Vellianitis, Heverlee (BE); Viraj Madhiwala, Kessel-Lo (BE); Sheng-Chih Lai, Hsinchu County (TW)

(73) Assignee: Taiwan Semiconductor Manufacturing Company, Ltd., Hsinchu (TW)

(21) Appl. No.: 19/086,046

(22) Filed: Mar. 20, 2025

(51) Int. Cl. H10D 30/67; H10D 64/68; H10D 62/80

(52) U.S. Cl. CPC H10D 30/6739; H10D 64/685; H10D 64/689; H10D 64/691; H10D 62/875

(57) ABSTRACT

A semiconductor structure includes a metal gate disposed over a substrate, a high-k material layer disposed over the metal gate, an inter layer disposed over the high-k material layer, an oxide semiconductor layer disposed on the inter layer, and source and drain terminals adjacent to the oxide semiconductor layer. The inter layer has a Gibbs free energy higher than hafnium oxide.

### BACKGROUND

In the semiconductor industry, there is a desirable object for increasing the areal density of integrated circuits, and thus thin film transistors (TFT) made of oxide semiconductors are developed to maintain or enlarge transistor size without increasing the areal density of integrated circuits. In attempting to achieve such object, a number of issues associated with the performance of the resulting transistors may be of interest.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor structure in accordance with some embodiments.

FIG. 2 illustrates a cross-sectional view of a semiconductor structure in accordance with some embodiments.

FIG. 3 illustrates a cross-sectional view of a semiconductor structure in accordance with some embodiments.

FIG. 4 illustrates a cross-sectional view of a semiconductor structure in accordance with some embodiments.

FIGS. 5A through 5F illustrate cross-sectional views of a process for the formation of a semiconductor structure in accordance with some embodiments.

FIG. 6 illustrates a top view of the semiconductor structure of FIG. 5F.

FIG. 7 illustrates a cross-sectional view of an integrated chip comprising a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “on,” “over,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to semiconductor structures, and particularly to thin film transistors (TFT) made of oxide semiconductors. A TFT is one type of metal-oxide-semiconductor field-effect transistor (MOSFET), and may be manufactured by depositing different layers on a substrate. The TFTs may be used in a number of commercial applications such as gate driver circuits, high-frequency display application, etc. Generally, a TFT is similar to a MOSFET in structure, and includes a gate terminal, a source terminal and a drain terminal. A semiconductor layer known as a channel layer is deposited to contact the source terminal and the drain terminal. Various materials have been proposed to be used for fabricating the TFTs. It may be beneficial to use oxide semiconductors to form some parts of the TFTs (e.g., the channel layer). For example, a ferroelectric field effect transistor (FeFET) includes a ferroelectric material which is employed as the gate insulator in a MOSFET. Ferroelectric materials have a charge polarization that can be switched in direction by an applied electric field. Since the forming of oxide semiconductors can be done without using processes such as doping activation annealing, the integration of the TFTs in a back end of line (BEOL) can be implemented in a low-temperature process to prevent damage to the devices that are already fabricated.

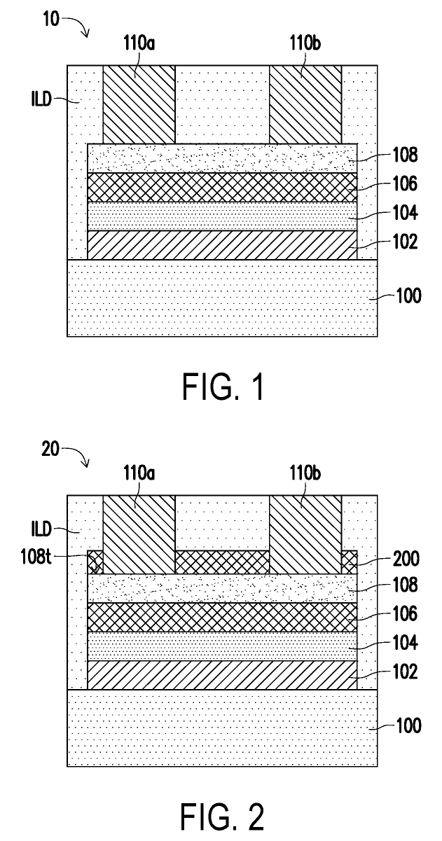

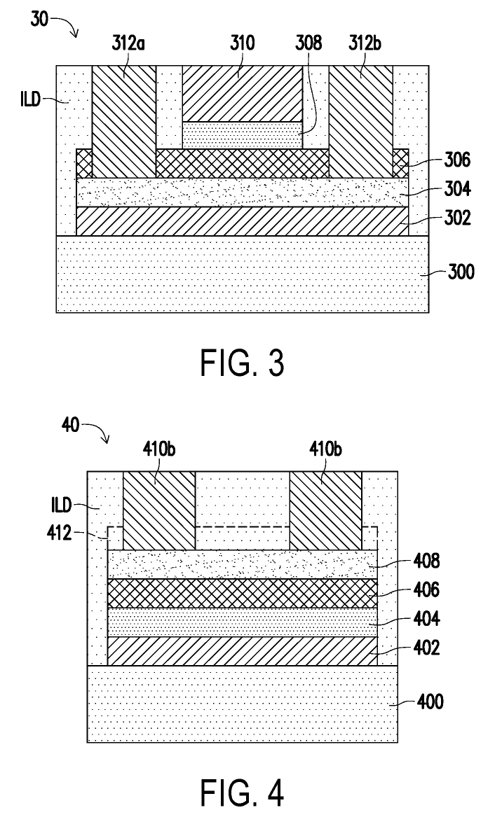

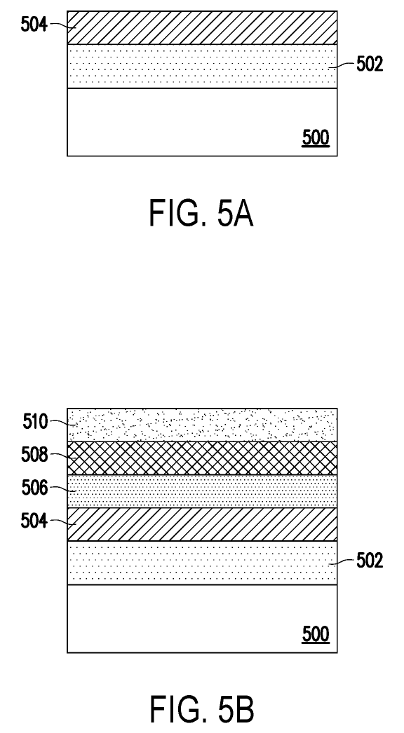

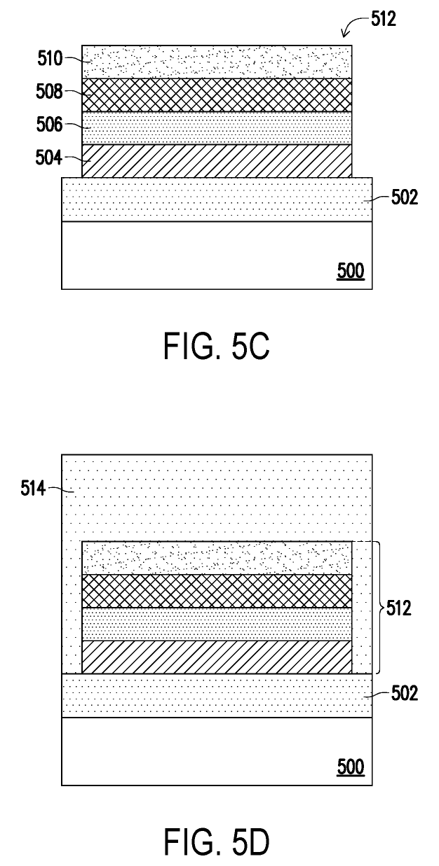

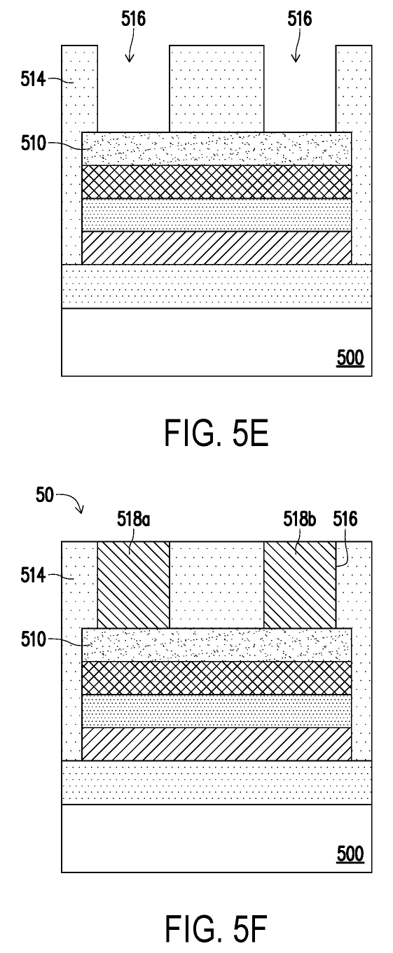

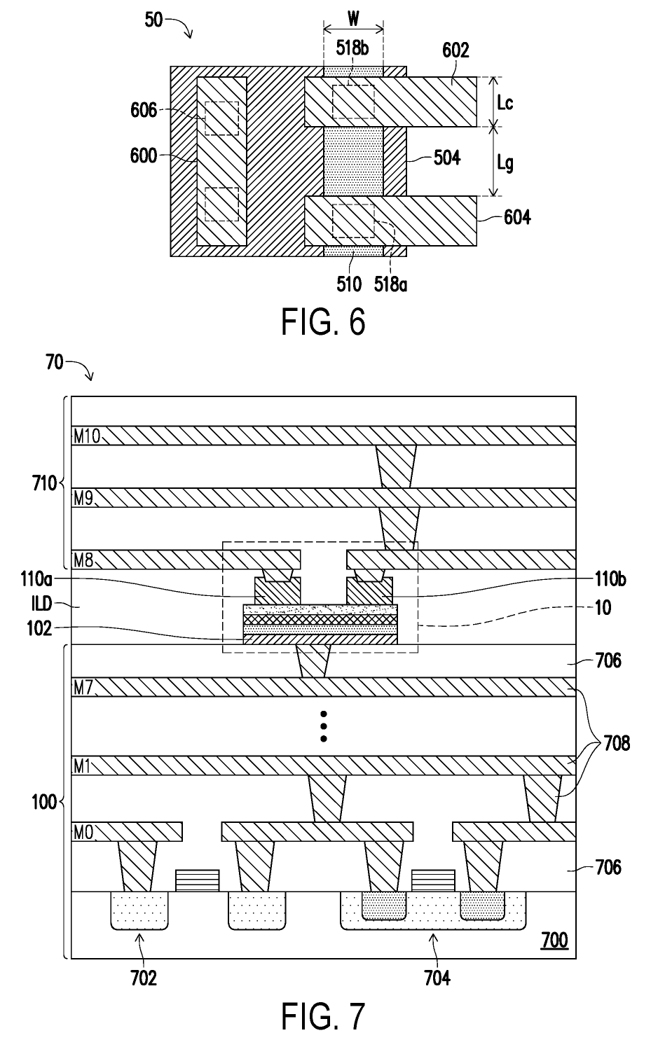

The various aspects of the present disclosure will now be discussed below with reference to FIGS. 1-6. In more detail, FIG. 1 illustrates an example of a semiconductor structure, in accordance with some embodiments of the present disclosure. FIG. 2 illustrates another example of a semiconductor structure, in accordance with some embodiments of the present disclosure. FIG. 3 illustrates yet another example of a semiconductor structure, in accordance with some embodiments of the present disclosure. FIG. 4 illustrates still yet another example of a semiconductor structure, in accordance with some embodiments of the present disclosure. FIGS. 5A-5F illustrate cross-sectional views of a semiconductor structure at various stages of fabrication according to embodiments of the present disclosure, and FIG. 6 illustrates a top view of the semiconductor structure of FIG. 5F. FIG. 7 illustrates a cross-sectional view of an integrated chip comprising a semiconductor structure in accordance with some embodiments of the disclosure.

It should be noted that embodiments discussed herein may not necessarily illustrate every component or feature that may be present in a structure. For example, multiples of a component may be omitted from a figure, such as when discussion of one of the component may be sufficient to convey aspects of the embodiment. Further, method embodiments discussed herein may be discussed as being performed in a particular order; however, other method embodiments may also be performed in any logical order.

FIG. 1 illustrates a cross-sectional view of a semiconductor structure 10 in accordance with some embodiments.

Referring now to FIG. 1, a semiconductor structure 10 includes a metal gate 102 disposed over a substrate 100, a high-k material layer 104 disposed over the metal gate 102, an inter layer 106 disposed over the high-k material layer 104, an oxide semiconductor layer 108 disposed on the inter layer 106, a source terminal 110aand a drain terminal 110b. In some embodiments, the substrate 100 may include a semiconductor substrate (not shown) and an interconnection (not shown) over the semiconductor substrate. In some embodiments, the substrate 100 may include one or more types of integrated circuits or electronic components therein. The semiconductor device(s) may be formed on a bulk semiconductor substrate or a silicon/germanium-on-insulator substrate. The embodiments are intended to provide further explanations but are not used to limit the scope of the disclosure. The source terminal 110aand the drain terminal 110bare adjacent to the oxide semiconductor layer 108. In some embodiments, the source terminal 110aand the drain terminal 110bare in direct contact with the oxide semiconductor layer 108. The inter layer 106 has a Gibbs free energy (ΔG) higher than hafnium oxide (HfO₂).

In case without the inter layer 106, hydrogen (H) from the high-k material layer 104 and the metal gate 102 may gradually diffuse into the oxide semiconductor layer 108 during operation. Since oxide semiconductor is sensitive to H, H leads to oxygen vacancies (V_{O}) in the oxide semiconductor layer 108; i.e. donor states of the oxide semiconductor layer 108. This phenomenon may cause NBTI (Negative-bias temperature instability)/PBTI (positive-bias temperature instability) shift resulting in reducing device performance. However, in the disclosure, a stable inter layer 106 is provided to prevent H diffusion. In other words, the inter layer 106 may act as a barrier layer and limit V_{O} formation, thereby improving bias temperature instability (BTI) of the semiconductor structure 10.

In some embodiments, a material of the inter layer 106 comprises calcium oxide (CaO), yttrium(III) oxide (Y₂O₃), lithium oxide (Li₂O), lanthanum(III) oxide (La₂O₃), strontium oxide (SrO), magnesium oxide (MgO), or barium oxide (BaO). Those oxides all have high ΔG at the same temperature, so those materials are highly stable and can block hydrogen diffusion during device operation at higher temperature such as 50° C. or more or 100° C. or more. The Gibbs free energy of CaO is greater than that of Y₂O₃. The Gibbs free energy of Y₂O₃ is greater than that of Li₂O. The Gibbs free energy of Li₂O is greater than that of La₂O₃. The Gibbs free energy of La₂O₃ is greater than that of MgO. The Gibbs free energy of MgOis greater than that of SrO. The Gibbs free energy of SrOis also greater than that of BaO. The Gibbs free energy of BaOis greater than that of HfO₂.

In some embodiments, a material of the inter layer 106 comprises M_{A}M_{B}O, wherein M_{A} and M_{B} are selected from Ca, Y, Li, La, Sr, Mg, and Ba respectively. For example, the material of the inter layer 106 may be CaYOₓ, CaLiOₓ, CaLaOₓ, CaSrOₓ, CaMgOₓ, CaBaOₓ, YLiOₓ, YLaOₓ, YSrOₓ, YMgOₓ, YBaOₓ, LiLaOₓ, LiSrOₓ, LiMgOₓ, LiBaOₓ, LaSrOₓ, LaMgOₓ, LaBaOₓ, SrMgOₓ, SrBaOₓ, or MaBaOₓ.

In some embodiments, the material of the inter layer 106 has a bandgap close to that of HfO₂. In general, hafnium oxide has a high bandgap of about 6 eV, and thus the bandgap of the material of the inter layer 106 is ranged from 4eV to 8eV. For example, calcium oxide has a bandgap of about 7.1 eV, yttrium(III) oxide has a bandgap of about 5.6 eV, lithium oxide has a bandgap of about 6.7 eV, lanthanum(III) oxide has a bandgap of about 5.8 eV, strontium oxide has a bandgap of about 5.45 eV, magnesium oxide has a bandgap of about 7.8 eV, and barium oxide has a bandgap of about 4.4 eV.

In some embodiments, the inter layer 106 has a nano-scale thickness; for instance, the nano-scale thickness is in a range of 1-50 nm, 1-30 nm, or 1-10 nm. In some embodiments, the inter layer 106 is deposited using a suitable deposition process such as chemical vapor deposition (CVD), such as plasma enhanced CVD (PECVD), low-pressure CVD (LPCVD), metal organic CVD (MOCVD), or atomic layer deposition (ALD). In some embodiments, the inter layer 106 is formed by epitaxy growth such as molecular beam epitaxy (MBE). In some other embodiments, the inter layer 106 is deposited by physical vapor deposition (PVD) such as evaporation, sputtering or ion plating.

In some embodiments, the metal gate 102 may include tungsten (W), tantalum nitride (TaN), titanium nitride (TiN), platinum (Pt), nickel (Ni), and/or other suitable materials and may be deposited using methods such as CVD, PVD, plating, and/or other suitable processes. In some embodiments, the metal gate 102 has a thickness of 5-1000 nm, e.g. 10-800 nm, or 50-700 nm.

In some embodiments, the high-k material layer 104 may be formed of a high-k dielectric material such as HfO₂, Al₂O₃, SiO₂, combinations thereof, or other suitable material and may be deposited using methods such as CVD, PVD, ALD, and/or other suitable processes. In some embodiments, the high-k material layer 104 has a thickness of 3-100 nm, e.g. 5-80 nm, or 10-50 nm.

In some embodiments, the oxide semiconductor layer 108 comprises an n-type semiconductor oxide which is served as an n-type channel, or the oxide semiconductor layer 108 comprises a p-type semiconductor oxide which is served as a p-type channel. In some embodiments, the n-type semiconductor oxide includes indium gallium zinc oxide (IGZO), indium oxide (InOₓ), indium tin oxide (ITO), indium tungsten oxide (IWO), etc. In some embodiments, the p-type semiconductor oxide includes nickel(II) oxide (NiO), tin(II) oxide (SnO), cuprous oxide (Cu₂O), etc. In some embodiments, the oxide semiconductor layer 108 has a thickness of 0.5-30 nm, e.g. 1-30 nm, or 1-20 nm.

In some embodiments, the source terminal 110a and the drain terminal 110b comprises metal or metal alloy. In an example, source or drain terminals 110a, 110bmay have a relatively low affinity for oxygen to limit gettering oxygen from the oxide semiconductor layer 108. In some embodiments, materials of the source or drain terminals 110a, 110binclude gold (Au), Pt, Ni, ITO, W, TiN, and/or other suitable materials. In some embodiments, the source or drain terminals 110a, 110b may have a thickness more than 5 nm, e.g. more than 10 nm, or more than 50 nm.

In some embodiments, a dielectric layer ILD is formed over the substrate 100 to cover the metal gate 102, the high-k material layer 104, the inter layer 106, the oxide semiconductor layer 108, the source terminal 110a and the drain terminal 110b. In some embodiments, the dielectric layer ILD is an interlayer dielectric layer. In some embodiments, the material of the dielectric layer ILD includes silicon oxide, silicon nitride, silicon oxynitride, or one or more low-k dielectric materials.

FIG. 2 illustrates a cross-sectional view of a semiconductor structure 20 in accordance with some embodiments. Unless specified otherwise, like reference numerals in this embodiment represent like components in the embodiment shown in FIG. 1. Accordingly, the process steps and applicable materials may not be repeated herein.

Referring now to FIG. 2, an upper layer 200 may be disposed on the oxide semiconductor layer 108 for covering a top surface 108t of the oxide semiconductor layer 108 except for the top surface 108t being in direct contact with the source terminal 110a and the drain terminal 110b. In some embodiments, the upper layer 200 has a nano-scale thickness; for instance, the nano-scale thickness is in a range of 1-50 nm, 1-30 nm, or 1-10 nm.

In some embodiments, the upper layer 200 has a Gibbs free energy higher than hafnium oxide. Accordingly, a material of the upper layer 200 may comprise calcium oxide (CaO), yttrium(III) oxide (Y₂O₃), lithium oxide (Li₂O), lanthanum(III) oxide (La₂O₃), strontium oxide (SrO), magnesium oxide (MgO), or barium oxide (BaO). In some embodiments, a material of the upper layer 200 comprises M_{A}M_{B}O, wherein M_{A} and M_{B} are selected from Ca, Y, Li, La, Sr, Mg, and Ba respectively. For example, the material of the upper layer 200 may be CaYOₓ, CaLiOₓ, CaLaOₓ, CaSrOₓ, CaMgOₓ, CaBaOₓ, YLiOₓ, YLaOₓ, YSrOₓ, YMgOₓ, YBaOₓ, LiLaOₓ, LiSrOₓ, LiMgOₓ, LiBaOₓ, LaSrOₓ, LaMgOₓ, LaBaOₓ, SrMgOₓ, SrBaOₓ, or MaBaOₓ.

The upper layer 200 may also prevent H diffusion, and thus it is conducive to improve BTI of the semiconductor structure 20 together with the inter layer 106. In some embodiments, a material of the upper layer 200 is identical to a material of the inter layer 106. Alternatively, a material of the upper layer 200 is different from a material of the inter layer 106.

FIGS. 1 and 2 illustrate back gated TFT architectures (e.g., top contact, bottom gate TFT architectures), where the source or drain terminals 110a, 110b are above the oxide semiconductor layer 108, and the metal gate 102 is below the oxide semiconductor layer 108.

However, teachings of this disclosure may also be applied to other appropriate TFT configuration as well, e.g., where the source or drain terminals and the metal gate are both above the oxide semiconductor layer. For example, FIG. 3 illustrates a cross-sectional view of a semiconductor structure 30 in accordance with some embodiments.

Referring to FIG. 3, a semiconductor structure 30 includes a first inter layer 302 disposed over a substrate 300, an oxide semiconductor layer 304, a second inter layer 306, a high-k material layer 308, a metal gate 310, a source terminal 312a and a drain terminal 312b. The substrate 300 may refer to the substrate 100 of above embodiments. The high-k material layer 308 is disposed over the second inter layer 306, and the metal gate 310 is disposed over the high-k material layer 308. The oxide semiconductor layer 304 is disposed on the first inter layer 302, and the second inter layer 306 is disposed on the oxide semiconductor layer 304. The first inter layer 302 has a Gibbs free energy higher than hafnium oxide, and the second inter layer 306 has a Gibbs free energy higher than hafnium oxide. The source terminal 312aand the drain terminal 312bare adjacent to the oxide semiconductor layer 304. In some embodiments, the source terminal 312aand the drain terminal 312b are in direct contact with the oxide semiconductor layer 304. In some embodiments, the source terminal 312a and the drain terminal 312b penetrate the second inter layer 306 to electrically connect with the oxide semiconductor layer 304.

In some embodiments, a material of the first inter layer 302 comprises CaO, Y₂O₃, Li₂O, La₂O₃, SrO, MgO, or BaO. In some embodiments, a material of the second inter layer 306 comprises CaO, Y₂O₃, Li₂O, La₂O₃, SrO, MgO, or BaO.

In some embodiments, a material of the first inter layer 302 comprises M_{A}M_{B}O, wherein M_{A} and M_{B} are selected from Ca, Y, Li, La, Sr, Mg, and Ba respectively. In some embodiments, a material of the second inter layer 306 comprises M_{A}M_{B}O, wherein M_{A} and M_{B} are selected from Ca, Y, Li, La, Sr, Mg, and Ba respectively. For example, the material of the first inter layer 302 or the second inter layer 306 may be CaYOₓ, CaLiOₓ, CaLaOₓ, CaSrOₓ, CaMgOₓ, CaBaOₓ, YLiOₓ, YLaOₓ, YSrOₓ, YMgOₓ, YBaOₓ, LiLaOₓ, LiSrOₓ, LiMgOₓ, LiBaOₓ, LaSrOₓ, LaMgOₓ, LaBaOₓ, SrMgOₓ, SrBaOₓ, or MaBaOₓ.

In some embodiments, a material of the first inter layer 302 is identical to a material of the second inter layer 306. Alternatively, a material of the first inter layer 302 is different from a material of the second inter layer 306. In some embodiments, the first inter layer 302 and the second inter layer 306 are deposited using a suitable deposition process such as CVD, PVD, ALD, or the like. In some embodiments, the first inter layer 302 and the second inter layer 306 both have a nano-scale thickness; for instance, the nano-scale thickness is in a range of 1-50 nm, 1-20 nm, or 1-10 nm.

Since the first inter layer 302 and the second inter layer 306 are stable, H diffusion from the high-k material layer 308 and the metal gate 310 can be avoided into the oxide semiconductor layer 304. Hence, the first inter layer 302 and the second inter layer 306 can limit V_{O} formation, thereby improving BTI of the semiconductor structure 30.

In some embodiments, the oxide semiconductor layer 304 comprises an n-type semiconductor oxide or a p-type semiconductor oxide. In some embodiments, the n-type semiconductor oxide includes IGZO, InOₓ, ITO, IWO, etc. In some embodiments, the p-type semiconductor oxide includes NiO, SnO, Cu₂O, etc. In some embodiments, the oxide semiconductor layer 304 has a thickness of 0.5-30 nm, e.g. 1-30 nm, or 1-20 nm.

In some embodiments, the high-k material layer 308 may be formed of a high-k dielectric material such as HfO₂, Al₂O₃, SiO₂, combinations thereof, or other suitable material and may be deposited using methods such as CVD, PVD, ALD, and/or other suitable processes. In some embodiments, the high-k material layer 308 has a thickness of 3-100 nm, e.g. 5-80 nm, or 10-50 nm.

In some embodiments, the metal gate 310 may include W, TaN, TiN, Pt, Ni, and/or other suitable materials and may be deposited using methods such as CVD, PVD, plating, and/or other suitable processes. In some embodiments, the metal gate 310 has a thickness of 5-1000 nm, e.g. 10-800 nm, or 50-700 nm.

In some embodiments, the source terminal 312a and the drain terminal 312b comprises metal or metal alloy. In an example, source or drain terminals 312a, 312bmay have a relatively low affinity for oxygen to limit gettering oxygen from the oxide semiconductor layer 108. In some embodiments, materials of the source or drain terminals 312a, 312b include Au, Pt, Ni, ITO, W, TiN, and/or other suitable materials. In some embodiments, the source or drain terminals 312a, 312b may have a thickness more than 5 nm, e.g. more than 10 nm, or more than 50 nm.

FIG. 4 illustrates a cross-sectional view of a semiconductor structure 40 in accordance with some embodiments.

Referring now to FIG. 4, a semiconductor structure 40 includes a metal gate 402 disposed over a substrate 400, a ferroelectric layer 404 disposed over the metal gate 402, an inter layer 406 disposed over the ferroelectric layer 404, an oxide semiconductor layer 408 disposed on the inter layer 406, a source terminal 410a and a drain terminal 410b. The source terminal 410aand the drain terminal 410bare adjacent to the oxide semiconductor layer 408. In some embodiments, the source terminal 410aand the drain terminal 410b are in direct contact with the oxide semiconductor layer 408. The inter layer 406 has a Gibbs free energy (ΔG) higher than hafnium oxide.

In some embodiments, a material of the inter layer 406 comprises CaO, Y₂O₃, Li₂O, La₂O₃, SrO, MgO, or BaO. In some embodiments, a material of the inter layer comprises M_{A}M_{B}O, wherein M_{A} and M_{B} are selected from Ca, Y, Li, La, Sr, Mg, and Ba respectively. For example, the material of the inter layer 406 may be CaYOₓ, CaLiOₓ, CaLaOₓ, CaSrOₓ, CaMgOₓ, CaBaOₓ, YLiOₓ, YLaOₓ, YSrOₓ, YMgOₓ, YBaOₓ, LiLaOₓ, LiSrOₓ, LiMgOₓ, LiBaOₓ, LaSrOₓ, LaMgOₓ, LaBaOₓ, SrMgOₓ, SrBaOₓ, or MaBaOₓ.

In some embodiments, the inter layer 406 is deposited using a suitable deposition process such as CVD, PVD, ALD, or the like. In some embodiments, the inter layer 406 has a nano-scale thickness; for instance, the nano-scale thickness is in a range of 1-50 nm, 1-20 nm, or 1-10 nm.

In some embodiments, the oxide semiconductor layer 408 comprises an n-type semiconductor oxide or a p-type semiconductor oxide. In some embodiments, the n-type semiconductor oxide includes IGZO, InOₓ, ITO, IWO, etc. In some embodiments, the p-type semiconductor oxide includes NiO, SnO, Cu₂O, etc. In some embodiments, the oxide semiconductor layer 408 has a thickness of 0.5-30 nm, e.g. 1-30 nm, or 1-20 nm.

In some embodiments, the ferroelectric layer 404 comprises a material that includes hafnium, zirconium, and oxygen , e.g., hafnium zirconium oxide (HfZrO, also referred to as HZO). In some embodiments, the ferroelectric layer 404 has a thickness of 3-100 nm, e.g. 5-80 nm, or 10-50 nm. Since the inter layer 406 is more stable than the ferroelectric layer 404, it may act as a barrier layer and prevent H diffusion from the ferroelectric layer 404 and the metal gate 402, such that BTI of the semiconductor structure 40 is improved.

In some embodiments, the metal gate 402 may include tungsten (W), tantalum nitride (TaN), titanium nitride (TiN), platinum (Pt), nickel (Ni), and/or other suitable materials and may be deposited using methods such as CVD, PVD, plating, and/or other suitable processes. In some embodiments, the metal gate 402 has a thickness of 5-1000 nm, e.g. 10-800 nm, or 50-700 nm.

In some embodiments, the substrate 400 may include a semiconductor substrate (not shown) and an interconnection (not shown) over the semiconductor substrate formed by front-end-of-line (FEOL) processes. In some embodiments, the substrate 400 may include one or more types of integrated circuits or electronic components therein. The semiconductor device(s) may be formed on a bulk semiconductor substrate or a silicon/germanium-on-insulator substrate. The embodiments are intended to provide further explanations but are not used to limit the scope of the present disclosure.

In some embodiments, the source terminal 410a and the drain terminal 410b comprises metal or metal alloy. In an example, source or drain terminals 410a, 410bmay have a relatively low affinity for oxygen to limit gettering oxygen from the oxide semiconductor layer 408. In some embodiments, materials of the source or drain terminals 410a, 410b include Au, Pt, Ni, ITO, W, TiN, and/or other suitable materials. In some embodiments, the source or drain terminals 410a, 410b may have a thickness more than 5 nm, e.g. more than 10 nm, or more than 50 nm.

In some embodiments, an upper layer 412 (illustrated by dotted line) may be disposed on the oxide semiconductor layer 408 for covering the oxide semiconductor layer 408. In some embodiments, the upper layer 412 has a Gibbs free energy higher than hafnium oxide. In some embodiments, a material of the upper layer 412 is identical to a material of the inter layer 406. Alternatively, a material of the upper layer 412 is different from a material of the inter layer 406.

FIGS. 5A through 5F illustrate cross-sectional views of a process for the formation of a semiconductor structure 50 in accordance with some embodiments.

With reference to FIG. 5A, a substrate 500 is provided having an oxide layer 502 thereon. The substrate 500 may be, for example, a material such as a glass, ceramic, dielectric, a semiconductor, the like, or a combination thereof. In some embodiments, the substrate 500 may be a semiconductor substrate, such as a bulk semiconductor or the like, which may be doped or undoped. The substrate 500 may be a wafer, such as a silicon wafer. Other substrates, such as a multi-layered or gradient substrate may also be used. In some embodiments, the oxide layer 502 may be, for example, a silicon oxide (SiO₂) or the like. A metallic material layer 504 is formed over the substrate 500. For example, the metallic material layer 504 may be formed by CVD, such as PECVD, LPCVD, MOCVD, or ALD. In some other embodiments, the metallic material layer 504 is formed by PVD such as evaporation, sputtering or ion plating.

Referring now to FIG. 5B, a high-k material layer 506 is formed over the metallic material layer 504. For example, the high-k material layer 506 may be formed by CVD, such as PECVD, LPCVD, MOCVD, or ALD. An inter layer 508 is formed over the high-k material layer 506, and the inter layer 508 may refer to the inter layer 106 of above embodiments, wherein the inter layer 508 has a Gibbs free energy (ΔG) higher than HfO₂. The inter layer 508 is deposited using a suitable deposition process such as CVD, PVD, atomic layer deposition (ALD), or the like. An oxide semiconductor layer 510 is then formed on the inter layer 508. For example, the oxide semiconductor layer 510 may be formed by CVD, ALD, PVD, or the like.

Referring now to FIG. 5C, a stack 512 is formed by patterning the oxide semiconductor layer 510, the inter layer 508, the high-k material layer 506, and the metallic material layer 504. The metallic material layer 504 acts as a metal gate of the resulting semiconductor structure. In some embodiments, the high-k material layer 506 and the metallic material layer 504 are patterned sequentially through multiple patterning processes.

Referring now to FIG. 5D, a dielectric layer 514 may be formed over the substrate 500 to cover the stack 512. In some embodiments, the dielectric layer 514 is an interlayer dielectric (ILD) layer. In some embodiments, the material of the dielectric layer 514 includes silicon oxide, silicon nitride, silicon oxynitride, or one or more low-k dielectric materials. The dielectric layer 514 may include one or more dielectric materials or one or more layers. In some embodiments, the dielectric layer 514 is formed to a suitable thickness through CVD (such as FCVD, PECVD, HDPCVD, SACVD and LPCVD), spin-on coating, or other suitable methods.

With reference to FIG. 5E, by etching the dielectric layer 514, a plurality of contact openings 516 is formed in the dielectric layer 514, and the oxide semiconductor layer 510 is exposed. In some embodiments, the formation of the contact openings 516 includes forming a patterned mask layer (not shown) over the dielectric layer 514, and anisotropic etching the dielectric layer 514 using the patterned mask layer as an etching mask until the oxide semiconductor layer 510 is exposed. The contact openings 516 have substantially vertical sidewalls in FIG. 5E. It is understood that the contact openings 516 may be formed with tapered or slant sidewalk within process variations.

With reference to FIG. 5F, a source terminal 518a and a drain terminal 518b are formed in the contact openings 516. In some embodiments, a barrier material (not shown) and optionally a seed material (not shown) are sequentially formed over the contact openings 516 and conformally covering the exposed surfaces of the contact openings 516, and a metallic material (not shown) is then filled into the contact openings 516 and fills up the contact openings 516 to form the source terminal 518a and the drain terminal 518b. The barrier material, the seed material and the metallic material may individually include one or more materials selected from tungsten (W), tantalum (Ta), titanium (Ti), platinum (Pt), nickel (Ni), alloys thereof, and nitrides thereof, for example. In some embodiments, the barrier material is formed by CVD or PVD. In some embodiments, the metallic material is formed by CVD or PVD. In alternative embodiments, the formation of the metallic material may include performing a plating process (such as, electrochemical plating). In some embodiments, the extra barrier material, the extra seed material and the extra metallic material may be removed by performing a planarization process, an etching process, or other suitable processes. In some embodiments, the planarization process may include performing a chemical mechanical polishing (CMP) process.

FIG. 6 illustrates a top view of the semiconductor structure 50 of FIG. 5F. FIG. 5F is the cross-sectional view along a line above the oxide semiconductor layer 510 of FIG. 6, and the line is parallel to an extending direction of the oxide semiconductor layer 510.

In FIG. 6, the metallic material layer 504 has a larger area than the oxide semiconductor layer 510, and a metal line 602 and a metal line 604 are disposed over the source terminal 518a and the drain terminal 518b. In some embodiments, a width W of the oxide semiconductor layer 510 is from 5 nm to 1000 nm. In some embodiments, a length LC of the metal line 602 is from 5 nm to 1000 nm, and the size of the source terminal 518a/the drain terminal 518b is same as or similar to the length LC. In some embodiments, a length Lg is from 5 nm to 100 nm, wherein the length Lg is a spacing between the metal line 602 and the metal line 604, or the length Lg is a spacing between the source terminal 518a and the drain terminal 518b.

In some embodiments, another metal line 600 is formed over the metallic material layer 504 and electrically connected to the metallic material layer 504 via a plurality of contact plugs 606. The contact plugs 606 may be formed together with the source terminal 518aand the drain terminal 518b. However, the disclosure is not limited thereto.

In some embodiments, additional steps may be provided before, during, and after the process steps depicted from FIGS. 5A to 5F, and some of the steps described above may be replaced or eliminated, for additional embodiments of the method. For example, an upper layer (not shown) may be added on the oxide semiconductor layer 510 before forming the dielectric layer 514, and the resulting structure is similar to the semiconductor structure 20 of FIG. 2. For example, the metallic material layer 504 is not formed first but is formed after forming the oxide semiconductor layer 510, and the resulting structure is similar to the semiconductor structure 30 of FIG. 3. For example, if the high-k material layer 506 is replaced by a ferroelectric material, and the resulting structure is similar to the semiconductor structure 40 of FIG. 4.

FIG. 7 illustrates a cross-sectional view of an integrated chip 70 comprising a semiconductor structure in accordance with some embodiments. Unless specified otherwise, like reference numerals in this embodiment represent like components in the embodiment shown in FIG. 1. Accordingly, the process steps and applicable materials may not be repeated herein.

Referring to FIG. 7, in some embodiments, the substrate 100 includes a semiconductor substrate 700. In one embodiment, the semiconductor substrate 700 comprises a crystalline silicon substrate or a doped semiconductor substrate (e.g., p-type semiconductor substrate or n-type semiconductor substrate). In some alternative embodiments, the semiconductor substrate 700 is made of other suitable elemental semiconductor, compound semiconductor, or alloy semiconductor.

In some embodiments, the substrate 100 includes transistors such as an NMOS 702 and a PMOS 704 formed in the semiconductor substrate 700. In one embodiment, the NMOS 702 and/or the PMOS 704 are formed following the complementary MOS (CMOS) processes. In some embodiments, the transistors such as the NMOS 702 and the PMOS 704 are formed in the substrate 100 during the front-end-of-line (FEOL) processes. In some other embodiments, the substrate 500 also includes one or more active component such as transistors, diodes, optoelectronic devices and/or one or more passive components such as capacitors, inductors and resistors.

In some embodiments, the substrate 100 includes metallization structures 708 embedded in an insulation layer 706. The insulation layer 706 and the metallization structures 708 are formed over the NMOS 702 and the PMOS 704. In some embodiments, the insulation layer 706 includes one or more dielectric layers. In some embodiments, the metallization structures 708 include interconnect structures, such as metal lines, vias and contact plugs. In some embodiments, the NMOS 702 and the PMOS 704 are electrically connected with the metallization structures 708, and the metal gate 102 of the semiconductor structure 10 is also electrically connected with the metallization structures 708. The metallization structures 708 shown herein are merely for illustrative purposes and the metallization structures 708 may include other configurations and may include one or more through vias and/or damascene structures.

The semiconductor structure 10 is formed over the substrate 100 as described in the embodiments of FIGS. 1 and 5A-5F. In some embodiments, the semiconductor structure 10 can be replaced by the semiconductor structure 20 of FIG. 2, the semiconductor structure 30 of FIG. 3, or the semiconductor structure 40 of FIG. 4. Moreover, in some embodiments, the integrated chip 70 may include the semiconductor structure 10, the semiconductor structure 20, the semiconductor structure 30, the semiconductor structure 40, or a combination thereof.

In some embodiments, an interconnect structure 710 is formed on the dielectric layer ILD and over the semiconductor structure 10, and thus the integrated chip 70 is formed. In some embodiments, the interconnect structure 710 includes one or multi-leveled routing lines and is in direct contact with the source terminal 110a and the drain terminal 110, so that the semiconductor structure 10 is electrically connected further to other components or devices. It is understood that the number and configurations of the routing lines of the interconnect structure 710 shown in FIG. 7 are merely for illustration, more of the routing lines may be formed in accordance with actual design requirements.

According to some embodiments, a semiconductor structure includes a metal gate disposed over a substrate, a high-k material layer disposed over the metal gate, an inter layer disposed over the high-k material layer, an oxide semiconductor layer disposed on the inter layer, and source and drain terminals adjacent to the oxide semiconductor layer. The inter layer has a Gibbs free energy higher than hafnium oxide.

According to some embodiments, a semiconductor structure includes a first inter layer disposed over a substrate, an oxide semiconductor layer disposed on the first inter layer, a second inter layer disposed on the oxide semiconductor layer, a high-k material layer disposed over the second inter layer, a metal gate disposed over the high-k material layer, and source and drain terminals adjacent to the oxide semiconductor layer. The first inter layer has a Gibbs free energy higher than hafnium oxide, and the second inter layer has a Gibbs free energy higher than hafnium oxide.

According to some embodiments, a semiconductor structure includes a metal gate disposed over a substrate, a ferroelectric layer disposed over the metal gate, an inter layer disposed over the ferroelectric layer, an oxide semiconductor layer disposed on the inter layer, and source and drain terminals adjacent to the oxide semiconductor layer. The inter layer has a Gibbs free energy higher than hafnium oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a metal gate disposed over a substrate;
a high-k material layer disposed over the metal gate;
an inter layer disposed over the high-k material layer, wherein the inter layer has a Gibbs free energy higher than hafnium oxide;
an oxide semiconductor layer disposed on the inter layer; and
source and drain terminals adjacent to the oxide semiconductor layer.

2. The semiconductor structure of claim 1, wherein a material of the inter layer comprises CaO, Y₂O₃ Li₂O, La₂O₃ SrO, MgO, or BaO.

3. The semiconductor structure of claim 1, wherein a material of the inter layer comprises M_{A}M_{B}O, wherein M_{A} and M_{B} are selected from Ca, Y, Li, La, Sr, Mg, and Ba respectively.

4. The semiconductor structure of claim 1, wherein the oxide semiconductor layer comprises an n-type semiconductor oxide or a p-type semiconductor oxide.

5. The semiconductor structure of claim 1, further comprising an upper layer disposed on the oxide semiconductor layer for covering a top surface of the oxide semiconductor layer except for the top surface being in direct contact with the source and drain terminals.

6. The semiconductor structure of claim 5, wherein the upper layer has a Gibbs free energy higher than hafnium oxide.

7. The semiconductor structure of claim 5, wherein a material of the upper layer is identical to a material of the inter layer.

8. The semiconductor structure of claim 5, wherein a material of the upper layer is different from a material of the inter layer.

9. A semiconductor structure, comprising:
a first inter layer disposed over a substrate, wherein the first inter layer has a Gibbs free energy higher than hafnium oxide;
an oxide semiconductor layer disposed on the first inter layer;
a second inter layer disposed on the oxide semiconductor layer, wherein the second inter layer has a Gibbs free energy higher than hafnium oxide;
a high-k material layer disposed over the second inter layer;
a metal gate disposed over the high-k material layer; and
source and drain terminals adjacent to the oxide semiconductor layer.

10. The semiconductor structure of claim 9, wherein a material of the first inter layer and a material of the second inter layer each independently comprises CaO, Y₂O₃ Li₂O, La₂O₃ SrO, MgO, or BaO.

11. The semiconductor structure of claim 9, wherein a material of the first inter layer and a material of the second inter layer each independently comprises M_{A}M_{B}O, wherein M_{A} and M_{B} are selected from Ca, Y, Li, La, Sr, Mg, and Ba respectively.

12. The semiconductor structure of claim 9, wherein the oxide semiconductor layer comprises an n-type semiconductor oxide or a p-type semiconductor oxide.

13. The semiconductor structure of claim 9, wherein a material of the first inter layer is identical to a material of the second inter layer.

14. The semiconductor structure of claim 9, wherein a material of the first inter layer is different from a material of the second inter layer.

15. A semiconductor structure, comprising:
a metal gate disposed over a substrate;
a ferroelectric layer disposed over the metal gate;
an inter layer disposed over the ferroelectric layer, wherein the inter layer has a Gibbs free energy higher than hafnium oxide;
an oxide semiconductor layer disposed on the inter layer; and
source and drain terminals adjacent to the oxide semiconductor layer.

16. The semiconductor structure of claim 15, wherein a material of the inter layer comprises CaO, Y₂O₃ Li₂O, La₂O₃ SrO, MgO, or BaO.

17. The semiconductor structure of claim 15, wherein a material of the inter layer comprises M_{A}M_{B}O, wherein M_{A} and M_{B} are selected from Ca, Y, Li, La, Sr, Mg, and Ba respectively.

18. The semiconductor structure of claim 15, wherein the oxide semiconductor layer comprises an n-type semiconductor oxide or a p-type semiconductor oxide.

19. The semiconductor structure of claim 15, wherein the ferroelectric layer comprises a material that includes hafnium, zirconium, and oxygen.

20. The semiconductor structure of claim 15, further comprising an upper layer disposed on the oxide semiconductor layer for covering a top surface of the oxide semiconductor layer except for the top surface being in contact with the source and drain terminals.
